(19) United States
(12) Patent Application Publication
(10) Pub. No.: US 2014/0268563 A1
(43) Pub. Date: Sep. 18, 2014

(54) METHOD AND APPARATUS FOR CONTROLLING HEAT IN POWER CONVERSION SYSTEMS

(71) Applicant: FINsix Corporation, Menlo Park, CA (US)

(72) Inventors: Anthony Sagneri, Menlo Park, CA (US); Vanessa Green, Menlo Park, CA (US)

(21) Appl. No.: 14/210,805

(22) Filed: Mar. 14, 2014

Related U.S. Application Data
(60) Provisional application No. 61/794,633, filed on Mar. 15, 2013.

(51) Int. Cl. H05K 7/20

(52) U.S. Cl. CPC H05K 7/20909
USPC 361/692

(57) ABSTRACT

A power module includes a housing and an AC/DC converter within the housing. The AC/DC converter is configured to convert an AC input signal into a DC output signal. The power module also includes an actuated heat removal device. The actuated heat removal device is configured to remove heat produced by the AC/DC converter from the housing.

### CROSS-REFERENCE TO RELATED APPLICATIONS

This application claims priority under 35 U.S.C. 119(e) to U.S. provisional application Ser. No. 61/794,633, titled “METHOD AND APPARATUS FOR CONTROLLING HEAT IN POWER CONVERSION SYSTEMS,” filed Mar. 15, 2013, which is hereby incorporated by reference in its entirety.

### DISCUSSION OF RELATED ART

Power adapters are widely used for powering and charging electronics, including consumer electronic devices such as cellular telephones and laptop computers, by way of example. A standard AC/DC power adapter converts the AC line voltage provided by a standard electrical outlet into a DC voltage accepted by an electronic device. A typical AC/DC power adapter for a laptop computer has a brick-shaped power conversion module with the necessary electronics for performing AC/DC power conversion. The power conversion module is attached to one cord with a plug that can be plugged into a standard electrical outlet and another cord with a connector that can be plugged into a laptop computer to power the laptop computer and/or charge its battery. A power adapter can provide voltage regulation, electrical isolation and protection from line surges.

Power adapters for consumer electronic devices tend to be large and heavy. In particular, power adapters for portable electronic devices that draw a larger amount of power (e.g., greater than 40 W), such as laptop computers, for example, are relatively large and heavy. Some power adapters for laptop computers can be more than 20% of the weight of the laptop computer itself. For a mobile device, such as a laptop computer, having a large and heavy power adapter can be particularly cumbersome, as the user may need to carry around such an adapter when the user expects to be away from a power outlet for any significant period of time.

### SUMMARY

Some embodiments relate to a power adapter. The power adapter includes a housing and an AC/DC converter within the housing. The AC/DC converter is configured to convert an AC input signal into a DC output signal. The power adapter also includes an actuated heat removal device. The actuated heat removal device is configured to remove heat produced by the AC/DC converter from the housing.

Some embodiments relate to a power adapter. The power adapter includes a housing and an AC/DC converter within the housing. The AC/DC converter is configured to convert an AC input signal into a DC output signal. The power adapter to also includes a sensor configured to detect proximity or touch of a human. The power adapter also includes an indicator device configured to produce an audible or visual output. The power adapter further includes a controller configured to control the at least one indicator device to produce the audible or visual output in response to the sensor detecting proximity or touch of a human.

Some embodiments relate to power module that includes a housing and an AC/DC converter within the housing. The AC/DC converter is configured to convert an AC input signal into a DC output signal. The power module also includes an actuated heat removal device. The actuated heat removal device is configured to remove heat produced by the AC/DC converter from the housing.

Some embodiments relate to a method. The method includes converting an AC input signal into a DC output signal using an AC/DC converter. The method also includes cooling the AC/DC converter by driving air through an enclosure for a power conversion module comprising the AC/DC converter.

The foregoing summary is provided by way of illustration, and is not intended to be limiting.

### BRIEF DESCRIPTION OF DRAWINGS

In the drawings, each identical or nearly identical component that is illustrated in various figures is represented by a like reference character. For purposes of clarity, not every component may be labeled in every drawing. The drawings are not necessarily drawn to scale, with emphasis instead being placed on illustrating various aspects of the techniques described herein.

FIG. 1 shows a perspective view of an example of a power adapter 1, according to some embodiments.

FIG. 2 shows a cross section of the power adapter of FIG. 1 along the dashed lines A-A.

FIG. 3 shows a side view illustrating the interior of the power adapter 1.

FIG. 4 shows a block diagram illustrating power and control circuitry 206, as well as optional sensors and an indicator device.

FIG. 5 shows a power adapter having a plurality of DC output connection ports.

### DETAILED DESCRIPTION

It would be desirable to reduce the size of power conversion electronics and associated control circuitry. Some embodiments relate to power conversion modules, such as power adapters, having AC/DC converters that are designed to convert a standard AC mains voltage into a DC voltage to provide power to an electronic device.

As mentioned above, power adapters for portable electronic devices that consume a substantial amount of power (e.g., greater than 40 W), such as laptop computers, for example, tend to be large and bulky. The present inventors have appreciated that there are two key limitations, either of which may prevent reducing the size of such a power adapter.

One limitation is the minimum size of the passive components (e.g., inductors and capacitors) used for power conversion. If the power conversion electronics utilizes a switched mode power converter that switches at typical power converter switching frequencies, the passive components needed for such a power converter may need to be prohibitively large to provide a sufficient amount of amount of energy storage during the switching intervals. When such a limitation applies, the size of the power adapter cannot be reduced, as the ability to reduce the size of the power adapter is limited by the size of the passive components.

Using a high frequency switching power converter can allow reducing the size of the passive components, thereby allowing the size of the power adapter to be reduced. However, when a high frequency switching power converter is used, the ability to reduce the size of the power adapter is no longer limited by the size of the passive components, but by the capability of removing heat from the power adapter. Power conversion circuitry, no matter how well designed to maximize efficiency, is less than 100% efficient, and the power that is lost is converted into heat. The smaller a power adapter is made, the more challenging it becomes to remove the heat that is produced by its power conversion electronics. Failing to remove the heat adequately can cause a rise in temperature that may reduce component lifetimes and/or cause the temperature of the power adapter to exceed acceptable standards for consumer electronic devices. For example, a power adapter with a plastic housing designed for consumer electronics applications is required to maintain an outside surface temperature of less than 85° C. to meet IEC and UL standards. Standard power adapters are not designed to remove a significant amount of heat produced in a small volume.

In accordance with some embodiments, techniques are described herein that enable forming power adapters of relatively small size that are capable of providing a significant amount of power to one or more electronic devices. The techniques described herein enable reliably removing heat from a power converter of small size. In some embodiments, a power adapter includes an actuated heat removal device, such as a fan, for example, that removes heat produced by the power adapter to enable keeping the temperature of the power adapter within an acceptable operating range. In some embodiments, one or more openings are provided in the housing of the power adapter to enable the ingress of cooler air from outside the housing and the egress of heated air. Such opening(s) may be provided on more than one side of the housing to provide redundancy in case opening(s) on one or more sides of the power adapter are blocked.

FIG. 1 shows a perspective view of an example of a power adapter 1, according to some embodiments. Power adapter 1 includes a housing 100 which may be formed of plastic or any other suitable material. As shown in FIG. 1, the housing 100 may have substantially a rectangular cuboid shape with a rectangular (e.g., square) cross-section. In some embodiments, the edges of the housing may be rounded or chamfered. However, the techniques described herein are not limited a rectangular cuboid shape, as housing 100 may have any suitable shape, such as a round shape. In some embodiments, the housing may be substantially flat (e.g., less than a half inch or a quarter inch in height along the vertical direction of FIG. 1).

A plug 102 is provided at one end of the power adapter 1. In the embodiment of FIG. 1, plug 102 is attached to an end cap 110 which may be affixed to the housing 100. Plug 102 may be shaped to plug into a standard electrical outlet. For example, plug 102 may be shaped to plug into a standard U.S. electrical outlet that provides an AC voltage of about 120V RMS. However, the techniques described herein are not limited in this respect, as power adapter 1 may be provided with a plug shaped to plug into any suitable electrical outlet. Further, the techniques described herein are not limited as to a plug 102 being disposed on the end of the power adapter 1, as in some embodiments a cord may be provided that is attached to the end of power adapter 1, and the cord may include a suitable plug.

The power adapter 1 may be connected to a cord 104 to enable connecting the to power adapter to an electronic device using connector 106. Connector 106 may have any of a variety of shapes suitable for connecting to a DC power input of a consumer electronic device.

FIG. 1 shows that the housing 100 may include one or more openings 108, 112 for allowing airflow into and/or out of the housing 100. In some embodiments, the power adapter may include an actuated heat removal device 202 (see, e.g., FIG. 3). The actuated heat removal device 202 may be a fan, for example, or another device capable of forcing airflow through the housing 100. If actuated heat removal device 202 includes a fan, any suitable type of fan may be used, such as a piezoelectric fan or an electrostatic fan, for example. In some embodiments, the fan is configured to draw cold air directly over the fan motor, thereby extending the fan's lifespan. Another suitable type of actuated heat removal device used in some embodiments is an electromechanical air pump (e.g., a bellows). An electromechanical air pump may drive puffs of air into and out of the housing. In some embodiments, if an electromechanical air pump is used, a portion of the housing may be operable as an actuatable member to drive the movement of air within the housing. The actuatable member may be a flexible membrane, in some embodiments. The actuatable member may be positioned in any location forming a contiguous space with the plenum.

In some embodiments, an actuated heat removal device may drive the flow of air toward or away from the power conversion circuitry of the power adapter 1. As mentioned above, FIG. 1 shows that one or more openings 112 and 108 may be provided on the housing 100 for enabling the flow of air into or out of the housing. In some embodiments, openings 112 may act as inlets to enable the flow of air into the housing 100 and openings 108 may act as outlets to enable the flow of air out of the housing 100. In some embodiments, one or more openings may be provided on each side of the housing 100 disposed along the longitudinal axis of the power adapter 1. In the embodiment of FIG. 1, the housing has four sides disposed along the longitudinal axis of the power adapter, each of which includes an opening 112 (e.g., an inlet) and an opening 108 (e.g., an outlet). FIG. 2 shows a cross section of the power adapter of FIG. 1 along the dashed lines A-A. As shown in FIG. 2, the power adapter may have four sides along the cross section defined by the dashed lines A-A. Each side of the power adapter along the longitudinal axis may have an opening 108 and/or an opening 112.

The inventors have appreciated that one or more sides of the power adapter may rest against one or more object(s) that may obstruct the flow of air through the openings 108 and/or 112, such as a floor, a wall, furniture, a blanket, etc. Accordingly, it may be desirable to provide openings to enable the flow of air through the housing on more than one side of the power adapter in case the flow of air through is obstructed by an object on one or more sides of the power adapter. By providing openings on more than one side of the power adapter, if a first side of the power adapter rests against an air-blocking object, airflow through the housing 100 may be provided through opening(s) on another side of the power adapter. In the embodiments of FIGS. 1-3, openings are provided on four sides of the power adapter, so that even if airflow on three sides of the power adapter is blocked, cooling may be provided by airflow through one or more openings on a fourth side of the power adapter. However the techniques described herein are not limited in this respect, as some embodiments are not limited as to the number of sides of the power adapter on which openings are disposed.

In some embodiments, if airflow through all of the openings in housing 100 is blocked, a controller may control the amount of power delivered by the power adapter to be reduced. The power adapter may include a temperature sensor to sense the internal temperature of the power adapter at the power conversion electronics or another location. When the temperature sensed by the temperature sensor exceeds a threshold, a controller may control the power conversion electronics such that the amount of power delivered at the output is reduced, or the delivery of power is ceased. When the power adapter cools and the temperature of the power adapter reaches a suitable operating point, the controller may control the power conversion electronics such that power delivery is be resumed and/or increased.

FIG. 3 shows a side view illustrating the interior of the power adapter 1. As shown in FIG. 3, the power adapter 1 includes power and control circuitry 206 which includes power electronics and control circuitry for converting the AC input signal (e.g., received at plug 102) into a DC output signal (e.g., provided via cord 104 to an external electronic device).

In some embodiments, power and control circuitry 206 may be disposed on a heat sink 204. The heat sink 204 may have protrusions 205 that provide a high surface area, to enabling the heat produced by power and control circuitry 206 to be dissipated in a plenum within the housing. Protrusions 205 may also produce turbulent airflow within the cavity, thereby facilitating the expulsion of heat from the surface of the heat sink 204. The protrusions 205 of heat sink 204 are also illustrated in FIG. 2.

As discussed above, the actuated heat removal device 202 may be a fan that blows air toward or away from the heat sink 204. In one embodiment, illustrated in FIG.

3, the actuated heat removal device 202 is configured to force air from one or more inlet openings 112 (shown in dashed lines) toward the heat sink 204 and out through one or more outlet openings 108 (also shown in dashed lines). However, the techniques described herein are not limited in this respect, as in some embodiments the actuated heat removal device 202 may be configured to drive airflow in the opposite direction.

In some embodiments, power and control circuitry 206 may be enclosed in an airtight enclosure (and optionally potted). Sealing the power and control circuitry 206 in an airtight enclosure can isolate power and control circuitry 206 from the plenum through which air passes, which can protect the power and control circuitry 206 from foreign substances such as liquid spills, dirt, dust, etc. In the event of failure of a component within the power and control circuitry 206, the use of an airtight enclosure to seal the power and control circuitry 206 can prevent the release of odorous gasses, which can facilitate compliance with FAA regulations, for example.

The actuated heat removal device may be controlled by power and control circuitry 206 through a suitable control connection within the housing 100 (not shown). Similarly, conductors (not shown) may be provided within the housing 100 to provide a connection between the plug 102 and the power and control circuitry 206.

Described above is an embodiment in which one or more openings in the housing 100 are provided on the sides of the power adapter 1. However, the techniques described herein are not limited to providing openings in the housing 100 on the sides of the power adapter 1, as in some embodiments one or more openings may be provided at the end(s) of the adapter. For example, if a plug 102 is included, an opening may be provided between the prongs of the plug to allow air to flow into and/or out of the power adapter 1. In some embodiments, one or more spacers may be included on the end cap 110 to ensure separation between the end cap 110 and the electrical socket, thereby creating a plenum.

FIG. 4 shows a block diagram illustrating power and control circuitry 206, as well as optional sensors and an indicator device, according to some embodiments. As shown in FIG. 4, power and control circuitry 206 is connected to receive an AC input voltage, such as an AC line voltage. An AC to DC converter 402 is configured to convert the AC input voltage into a DC output voltage. In some embodiments, AC to DC converter 402 may include a rectifier followed by a DC/DC converter. The DC/DC converter may operate at a relatively high switching frequency, such as in the VHF range (30 MHz to 300 MHz), and may utilize resonant switching techniques and/or soft switching techniques to maximize efficiency. Suitable power conversion circuitry is described in PCT application WO 2012/024542 (PCT/US2011/048326), filed Aug. 18, 2011, which is hereby incorporated by reference in its entirety. However, the techniques described herein are not limited in this respect, as other suitable types of AC/DC converters may be used.

Controller 404 may control the operation of AC/DC converter 402 and actuated heat removal device 202 using suitable control signals provided thereto. In some embodiments, as discussed above, controller 404 may receive a signal from temperature sensor 406, and may control the AC/DC converter 402 to reduce the amount of power that is delivered when the temperature exceeds a threshold. In some embodiments, controller 404 may increase or decrease the actuation of actuated heat removal device 202 (e.g., if a fan is used, the speed of the fan may be changed) in response to the temperature signal from temperature sensor 406.

In some embodiments, the power adapter 1 may include a touch or proximity sensor 408, to detect when a person (e.g., a hand, for example) comes close to or touches the power adapter 1. In response to a signal detected by the touch or proximity sensor 408, a human-perceptible effect may be produced. For example, the power adapter may include an indicator device 410, such as a lighting device (e.g., an LED) to produce light, and/or a device that can produce an audible sound. In response to a signal detected by the touch or proximity sensor 408, the indicator device 410 may be turned on. For example, a lighting device may illuminate, which may assist a user in finding the power adapter in the dark. As another example, an audible sound may be played, which may assist a user in finding an adapter that is in a difficult to reach location (e.g., under or behind furniture, for example). In some embodiments, if an indicator device 410 is to included, the power adapter 1 may include an energy storage device such as a battery or ultracapacitor to provide power to the indicator device.

In some embodiments, the controller 404 may be configured to change the actuation of the actuated heat removal device 202 in response to detecting touch or proximity of a person. For example, in some embodiments the actuation of the actuated heat removal device 202 may be reduced or stopped in response to detecting touch or proximity of a human hand.

In some embodiments, controller 404 may measure an amount of power provided to input of the power adapter and/or at the output of the power adapter. The power adapter may have an interface, such as a wired or wireless interface (e.g., a WiFi or Bluetooth interface device) to enable communication with an external device. The power adapter may send information regarding the measured power and/or total energy to the external device (e.g., a laptop computer, tablet computer, smartphone or server) so that a person (e.g., a user) can view the information to find out how much power is consumed by a device connected to the output of the power adapter.

In some embodiments, a power adapter may include one or more DC output connection ports that enable one or more cords to be removably connected thereto. In some embodiments, one or more cords may be provided having electrical connector(s) designed to connect to the DC output connection port(s) of the power adapter. The cord's connector may be held in place at the DC output connection port using any suitable technique, such as a mechanical connection and/or through magnetic attraction.

FIG. 5 shows that the power adapter 1 may have a plurality of DC output connection ports 501, 502 and 503. The side of the power adapter shown in FIG. 5 may correspond to the end of the power adapter that is on the left side of FIG. 1, to which cord 104 is connected. As shown in FIG. 5, cord 104 may have a connector 505 configured to removably connect to DC output connection port 501. Cord 104 may have a connector 106 for connecting to a first type of electronic device (e.g., a laptop). Other cords may be provided having the same type of connector 505 but different connectors 106 for connecting to other types of electronic devices (e.g., smart phones, tablet computers, etc.). Such cords may be provided in a kit along with the power adapter, in some embodiments. Accordingly, a user may select a suitable cord having the appropriate connector 106 to connect to a device that the user wishes to power and/or charge. Advantageously, power adapter 1 may be a universal power adapter that is capable of charging a plurality of different devices (e.g., laptops, cellular telephones, tablet computers, etc.). Accordingly, a user may travel with one small universal power adapter that is capable of charging multiple different devices, rather than carrying multiple power adapters dedicated to each of the user's devices.

In some embodiments, each cord that may be connected to DC output connection port 501 may be individually identifiable by the power adapter when it is plugged in. For example, when a user plugs in a particular type of cord to a DC output connection port, the power adapter may determine the type of cord that is plugged in. Such a determination may be made in any of a variety of ways. For example, the cord may be designed to have a certain impedance when measured, and the power adapter may perform an impedance measurement on a cord when it is connected to identify it. As another example, the cord may be provided with an integrated circuit that identifies the cord. Such an integrated circuit may be provided in connector 505 and/or connector 106, by way of example. As another example, a cord may be identified based on time domain reflectometry. Any suitable technique for identifying a cord may be used.

The power adapter 1 may determine a suitable DC output voltage to be provided based on identification of the cord. For example, when a first cord is plugged in, the power adapter may identify the cord as being designed to provide a 5V DC output voltage. Accordingly, the controller 404 may control the AC/DC converter 402 to provide a 5V DC output voltage to the corresponding DC output port to which the cord is connected. If another cord is later plugged into the same DC output port, the power adapter may identify the cord as being designed to provide a 9V DC output voltage. Accordingly, the controller 404 may control the AC/DC converter 402 to provide a 9V DC output voltage to the DC output port.

In some embodiments, power adapter 1 is capable of powering and/or charging a plurality of devices at the same time. For example, a first connector of a first cord may plug into DC output connection port 501 for powering a laptop, a second connector of a second cord may plug into a DC output connection port 502 for powering a cellular telephone, and/or a third cord may plug into DC output connection port 503 for powering another device. In a power adapter 1 configured to power and/or charge a plurality of devices at a time, the AC/DC converter may be configured to provide a plurality of DC outputs of suitable output voltages to the respective DC output connection ports. The output voltages of the DC outputs may be different, to enable charging different types of devices, or may be the same.

DC output connection ports 501, 502 and 503 may be the ports of the same shape and type or ports of different shapes and/or types to accept different types of connectors. In some non-limiting embodiments, one or more of the DC output connection ports may be USB ports (e.g., USB 3.0 ports). However, the techniques described herein are not limited as to the particular types of connection port(s) employed.

As discussed above, the power adapter 1 described herein is capable of providing significant output power in a small sized housing. In some embodiments, the volume of the power adapter (excluding cords) may be relatively small, such as 3 cubic inches or less, or 2 cubic inches or less. For example, in some embodiments the power adapter may be about 2 inches in length or less, about 1 inch in width, or less and about 1 inch in height or less. In some embodiments, the output power provided by the power adapter is at least 30 W, such as at least 40 W, at least 45 W at least 60 W, at least 80 W, or at least 100 W or higher. In some embodiments, the power converter may provide a power conversion density 50 W/in³ or higher.

Described above is a power adapter which may be used for powering and/or charging consumer electronic devices. However, the techniques described herein are not limited to power adapters for consumer electronic devices. Some embodiments relate to a power conversion module for other electronic devices, such as servers or other devices in a data center, which may benefit from a reduction in size of the power electronics. Other non-limiting examples of applications include power electronics for industrial equipment and electronics for automobiles, aircraft and ships.

Various aspects of the apparatus and techniques described herein may be used alone, in combination, or in a variety of arrangements not specifically discussed in the embodiments described in the foregoing description and is therefore not limited in its application to the details and arrangement of components set forth in the foregoing description or illustrated in the drawings. For example, aspects described in one embodiment may be combined in any manner with aspects described in other embodiments.

Use of ordinal terms such as “first,” “second,” “third,” etc., in the claims to modify a claim element does not by itself connote any priority, precedence, or order of one claim element over another or the temporal order in which acts of a method are performed, but are used merely as labels to distinguish one claim element having a certain name from another element having a same name (but for use of the ordinal term) to distinguish the claim elements.

Also, the phraseology and terminology used herein is for the purpose of description and should not be regarded as limiting. The use of “including,” “comprising,” or “having,” “containing,” “involving,” and variations thereof herein, is meant to encompass the items listed thereafter and equivalents thereof as well as additional items.

What is claimed is:

1. A power adapter, comprising:
a housing;
an AC/DC converter within the housing, the AC/DC converter being configured to convert an AC input signal into a DC output signal; and
an actuated heat removal device, the actuated heat removal device being configured to remove heat produced by the AC/DC converter from the housing,
wherein the volume of the power adapter is no more than 3 cubic inches, and
wherein the power adapter is configured to deliver an output power of at least 30 watts.

2. The power adapter of claim 1, wherein the housing comprises at least one opening through which heat is transferred by the heat removal device.

3. The power adapter of claim 2, wherein the at least one opening comprises at least one inlet and at least one outlet.

4. The power adapter of claim 2, wherein the housing has a plurality of openings on a plurality of sides of the housing to provide airflow in the case of blocking of one or more openings of the plurality of openings.

5. The power adapter of claim 1, wherein the actuated heat removal device is configured to drive movement of air through an opening in the housing.

6. The power adapter of claim 5, wherein the actuated heat removal device comprises a fan.

7. The power adapter of claim 6, wherein the fan has a motor and the fan is configured to draw cold air directly over the motor.

8. The power adapter of claim 1, wherein the actuated heat removal device comprises a bellows that produces air movement within the housing.

9. The power adapter of claim 8, wherein a portion of the housing forms a movable portion of the bellows.

10. The power adapter of claim 1, further comprising:
a controller configured to switch the AC/DC converter at a VHF frequency.

11. The power adapter of claim 1, wherein the AC input signal comprises a utility line voltage and the DC output signal has a DC voltage suitable for charging and/or powering a consumer electronic device.

12. The power adapter of claim 1, wherein the housing has substantially a rectangular cuboid shape.

13. The power adapter of claim 1, wherein the housing is no larger than 2 cubic inches in volume.

14. The power adapter of claim 1, wherein the power adapter is configured to charge any of a laptop computer, a tablet computer, and a smart phone.

15. The power adapter of claim 1, wherein the power adapter is configured to charge a plurality of consumer electronic devices at a time.

16. The power adapter of claim 1, wherein the power adapter comprises a plurality of DC output connection ports.

17. A kit comprising:
the power adapter of claim 1, wherein the power adapter further comprises at least one output connector configured to provide a DC voltage; and
a plurality of cords having connectors configured to attach to the at least one output connector.

18. The kit of claim 17, wherein the plurality of cords comprises a first cord having a first connector configured to attach to a first type of power connector of a first consumer electronic device and a second cord having a second connector configured to attach to a second type of power connector of a second consumer electronic device.

19. The power adapter of claim 1, further comprising:
a controller configured to control the AC/DC converter, wherein the controller is configured to change an amount of output power produced by the AC/DC converter based on a temperature of the AC/DC converter.

20. The power adapter of claim 1, further comprising:
a sensor configured to detect proximity or touch of a human.

21. The power adapter of claim 20, further comprising:
a controller configured to change actuation of the actuated heat removal device in response to the sensor detecting proximity or touch of a human.

22. The power adapter of claim 21, further comprising:
an indicator device configured to produce an audible or visual output, wherein the controller is configured to control the indicator device to produce the audible or visual output in response to the sensor detecting proximity or touch of a human.

23. A power adapter, comprising:
a housing;
an AC/DC converter within the housing, the AC/DC converter being configured to convert an AC input signal into a DC output signal;
a sensor configured to detect proximity or touch of a human;
an indicator device configured to produce an audible or visual output, and
a controller configured to control the indicator device to produce the audible or visual output in response to the sensor detecting proximity or touch of a human.

24. The power adapter of claim 23, wherein the indicator device comprises a light emitting device and the controller is configured to turn on the light emitting device in response to the sensor detecting proximity or touch of a human.

25. A power module, comprising:
a housing;
an AC/DC converter within the housing, the AC/DC converter being configured to convert an AC input signal into a DC output signal; and
an actuated heat removal device, the actuated heat removal device being configured to remove heat produced by the AC/DC converter from the housing,
wherein the volume of the power module is no more than 3 cubic inches, and
wherein the power module is configured to deliver an output power of at least 30 watts.

26. A method, comprising:
converting an AC input signal into a DC output signal using an AC/DC converter; and
cooling the AC/DC converter by driving air through an enclosure for a power conversion module comprising the AC/DC converter, wherein the volume of the power module is no more than 3 cubic inches, and
delivering, by the power conversion module, an output power of at least 30 watts.
